(19) United States
(12) Patent Application Publication
(10) Pub. No.: US 2007/0161189 A1
(43) Pub. Date: Jul. 12, 2007

(54) METHOD OF FABRICATING THE FLOATING GATE OF FLASH MEMORY DEVICE

(76) Inventor: Seong-Gyun Kim, Seoul (KR)

Correspondence Address: SHERR & NOURSE, PLLC, 620 HERNDON PARKWAY, SUITE 200, HERNDON, VA, 20170, US

(21) Appl. No.: 11/612,284

(22) Filed: Dec. 18, 2006

(30) Foreign Application Priority Data
Dec. 19, 2005 (KR) 10-2005-0125644

(51) Int. Cl. H01L 21/336

(52) U.S. Cl. 438/257; 257/E29.3

(57) ABSTRACT

There is provided a method of forming a floating gate of a flash memory device, including forming a tunnel insulating layer over a semiconductor substrate; forming a floating gate conductive layer over the tunnel insulating layer; forming a hard mask layer pattern over the floating gate conductive layer; forming a second conductive layer over exposed surfaces of the hard mask layer pattern and the floating gate conductive layer; etching the second conductive layer to form a conductive spacer layer over sidewalls of the hard mask layer pattern; oxidizing the conductive spacer layer and the floating gate conductive layer to form a mask oxide layer and a spacer oxide layer; removing the hard mask layer pattern to partially expose a surface of the floating gate conductive layer; and removing the exposed portion of the floating gate conductive layer by performing an etching process using the mask oxide layer and the spacer oxide layer as etch masks so as to form a floating gate pattern.

The present application claims priority under 35 U.S.C. 119 and 35 U.S.C. 365 to Korean Patent Application No. 10-2005-0125644 (filed on Dec. 19, 2005), which is hereby incorporated by reference in its entirety.

### BACKGROUND

FIGS. 1 to 5 are cross-sectional views illustrating a method of forming the floating gate of a flash memory device.

First, a tunnel insulating layer 110, a floating gate conductive layer 120, and a hard mask layer 130 are sequentially stacked over a semiconductor substrate 100, as shown in FIG. 1. The tunnel insulating layer 110 is formed of an oxide layer; the floating gate conductive layer 120 is formed of a polysilicon layer; and the hard mask layer 130 is formed of a nitride layer.

Thereafter, a predetermined mask layer pattern, e.g., a photoresist layer pattern (not shown) is formed as shown in FIG. 2. The hard mask layer 130 is subjected to an etching process using the photoresist layer pattern as an etch mask so as to form a hard mask layer pattern 132 which partially exposes the surface of the floating gate conductive layer 120. After the hard mask layer pattern 132 is formed, the photoresist layer pattern is removed.

Subsequently, the floating gate conductive layer 120 exposed by the hard mask layer pattern 132 is subject to an oxidation process so as to form a mask oxide layer 140 in a local oxidation of silicon (LOCOS) structure, as shown in FIG. 3.

The hard mask layer pattern 132 is then removed, as shown in FIG. 4. If the hard mask layer pattern 132 is formed of a nitride layer, the hard mask layer pattern 132 may be removed using, for example, a wet-cleaning process.

The exposed portion of the floating gate conductive layer 120 is then removed through an etching process using the mask oxide layer 140 as an etch mask so as to form floating gate patterns 122, as shown in FIG. 5.

With this method, a bird's beak is inevitably produced in the process of forming the mask oxide layer 140 in the LOCOS structure as described in FIG. 3. Accordingly, an interval (d1 in FIG. 3) between the neighboring floating gate patterns 122 must be secured in consideration of the length of the bird's beak, which limits the reduction of a cell area.

### SUMMARY

Embodiments relate to a method of fabricating a flash memory device, and more particularly, to a method of forming a floating gate of a flash memory device.

Embodiments relate to a method of forming a floating gate of a flash memory device which is capable of reducing a cell area by reducing an interval between adjacent floating gate patterns.

In accordance with embodiments, a method is provided for forming a floating gate of a flash memory device, and the method includes forming a tunnel insulating layer over a semiconductor substrate; forming a floating gate conductive layer over the tunnel insulating layer; forming a hard mask layer pattern over the floating gate conductive layer; forming a second conductive layer over exposed surfaces of the hard mask layer pattern and the floating gate conductive layer; etching the second conductive layer to form a conductive spacer layer over sidewalls of the hard mask layer pattern; oxidizing the conductive spacer layer and the floating gate conductive layer to form a mask oxide layer and a spacer oxide layer; removing the hard mask layer pattern to partially expose a surface of the floating gate conductive layer; and removing the exposed portion of the floating gate conductive layer by performing an etching process using the mask oxide layer and the spacer oxide layer as etch masks so as to form a floating gate pattern.

Each of the floating gate conductive layers and the conductive layer may be formed of a polysilicon layer.

The hard mask layer pattern may be formed of a nitride layer.

The etching of the conductive layer to form a conductive spacer layer over sidewalls of the hard mask layer pattern may be performed using anisotropic dry-etching.

### BRIEF DESCRIPTION OF THE DRAWINGS

FIGS. 1 to 5 are cross-sectional views illustrating a method of forming a floating gate of a flash memory device; and

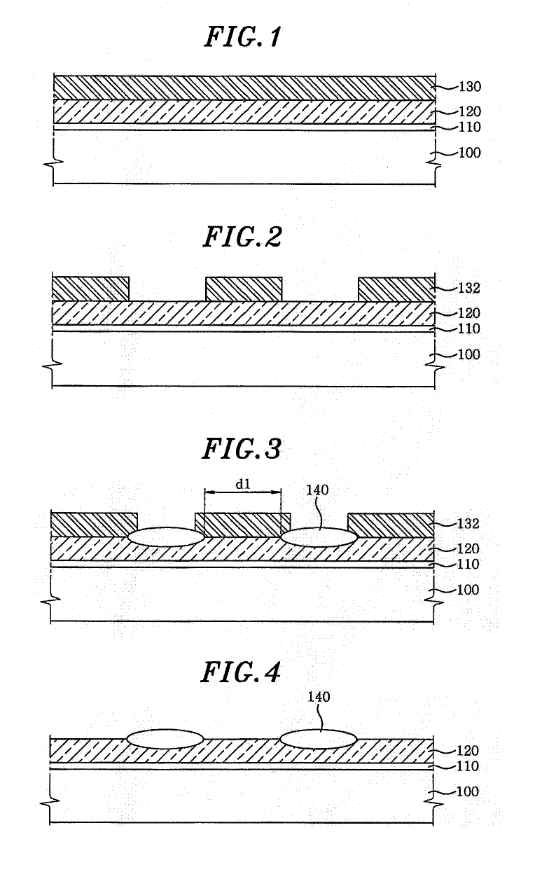

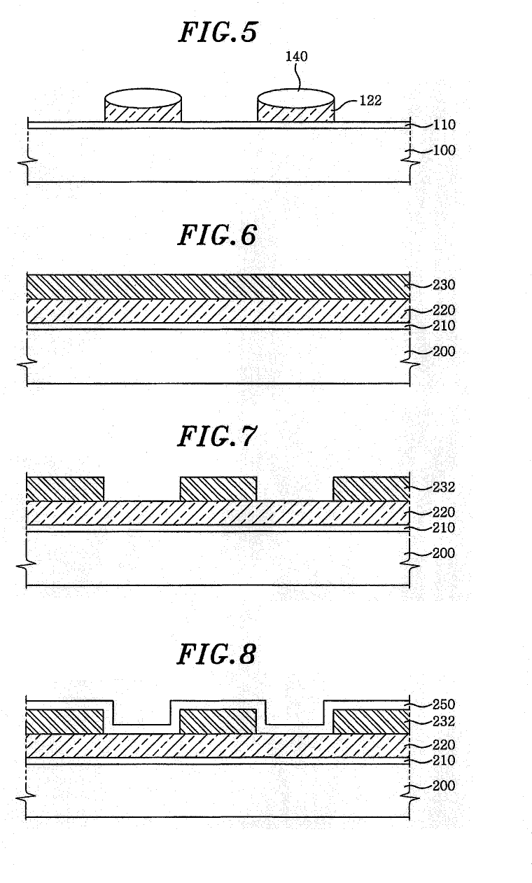

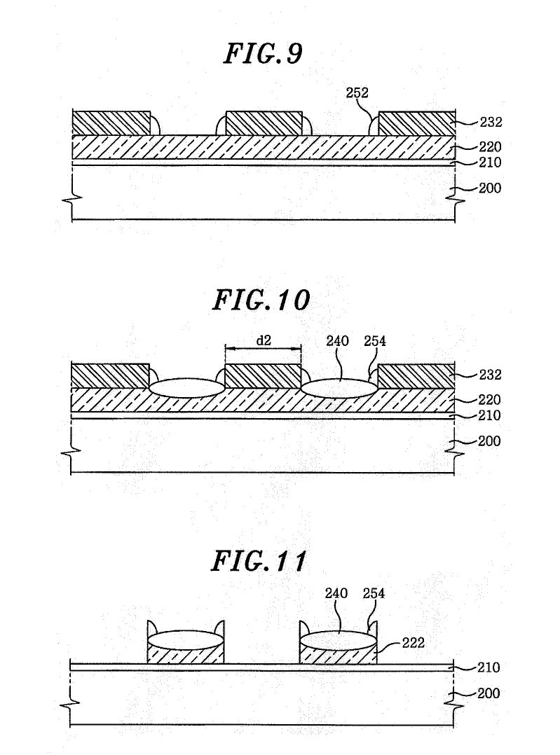

Example FIGS. 6 to 11 are cross-sectional views illustrating a method of forming a floating gate of a flash memory device in accordance with embodiments.

### DETAILED DESCRIPTION

As shown in FIG. 6, a tunnel insulating layer 210, a floating gate conductive layer 220, and a hard mask layer 230 are sequentially formed over a semiconductor substrate 200. The tunnel insulating layer 210 may be an oxide layer. The floating gate conductive layer 220 may be a polysilicon layer. The hard mask layer 230 may be a material having oxidation selectivity with respect to the floating gate conductive layer 220, i.e., a material that is not oxidized when a top surface of the floating gate conductive layer 220 is being oxidized. The floating gate conductive layer 220 may be formed of a nitride layer.

The hard mask layer 230 is then patterned to form a hard mask layer pattern 232 having openings that partially expose the surface of the floating gate conductive layer 220, as shown in FIG. 7. Specifically, a photoresist layer (not shown) is first formed over the hard mask layer 230. This photoresist layer is subject to exposure and development to form a photoresist layer pattern that partially exposes the surface of the hard mask layer 230. The exposed portion of the hard mask layer 230 is then removed through an etching process using the photoresist layer pattern as an etch mask. Accordingly, the hard mask layer pattern 232 is formed which partially exposes the surface of the floating gate conductive layer 220. After the hard mask layer pattern 232 is formed, the photoresist layer pattern is removed.

A conductive layer 250 is then formed over the exposed surface of the floating gate conductive layer 220 and the hard mask layer pattern 232, as shown in FIG. 8. The conductive layer 250 is composed of a material that can be oxidized in a subsequent oxidation process in which a mask oxide layer is formed. The conductive layer 250 may be a polysilicon layer. In this case, the thickness of the conductive layer 250 depends on the desired thickness of a conductive spacer layer formed in the subsequent process.

The conductive layer 250 is then etched to form a conductive spacer layer 252 located over sidewalls of the hard mask layer pattern 232, as shown in FIG. 9. The conductive layer 250 may be etched using anisotropic dry-etching, e.g., etch back to form the conductive spacer layer 252. The top surface of the hard mask layer pattern 232 is again exposed.

The floating gate conductive layer 220 and the conductive spacer layer 252 are then subject to an oxidation process so as to form a mask oxide layer 240 in a local oxidation of silicon (LOCOS) structure and a spacer oxide layer 254, as shown in FIG. 10. The spacer oxide layer 254 formed by oxidizing the conductive spacer layer 252 suppresses the production of a bird's beak upon the formation of the mask oxide layer 240 of the LOCOS structure. Because of the bird's beak suppression, an interval d2 between the adjacent mask oxide layer 240 can be reduced by the width of the spacer oxide layer 254, thereby reducing an entire cell area.

The hard mask layer pattern 232 is then removed using, for example, a wet-cleaning method, as shown in FIG. 11. Accordingly, the surface of the floating gate conductive layer 220 is partially exposed by the mask oxide layer 240 and the spacer oxide layer 254. The exposed portion of the floating gate conductive layer 220 is removed using the mask oxide layer 240 and the spacer oxide layer 254 as etch masks to form a floating gate pattern 222.

As described above, with the method of forming a floating gate of a flash memory device in accordance with embodiments, the production of a bird's beak can be minimized by forming the spacer layer as the polysilicon layer and then, performing an oxidation process to form the mask oxide layer, thereby reducing the interval between the adjacent floating gate patterns and reducing the cell area.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a tunnel insulating layer over a semiconductor substrate;
forming a floating gate conductive layer over the tunnel insulating layer;
forming a hard mask layer pattern over the floating gate conductive layer;
forming a second conductive layer over exposed surfaces of the hard mask layer pattern and the floating gate conductive layer;
etching the second conductive layer to form a conductive spacer layer over sidewalls of the hard mask layer pattern;
oxidizing the conductive spacer layer and the floating gate conductive layer to form a mask oxide layer and a spacer oxide layer;
removing the hard mask layer pattern to partially expose a surface of the floating gate conductive layer; and
removing the exposed portion of the floating gate conductive layer by performing an etching process using the mask oxide layer and the spacer oxide layer as etch masks so as to form a floating gate pattern.

2. The method of claim 1, wherein each of the floating gate conductive layer and the second conductive layer is formed of a polysilicon layer.

3. The method of claim 1, wherein the hard mask layer pattern is a nitride layer.

4. The method of claim 1, wherein the etching of the conductive layer to form a conductive spacer layer over sidewalls of the hard mask layer pattern is performed using anisotropic dry-etching.
